(19) United States
(12) Patent Application Publication
(10) Pub. No.: US 2007/0096767 A1
(43) Pub. Date: May 3, 2007

(54) METHOD OF PREVENTING DISPLAY PANEL FROM BURN-IN DEFECT

(76) Inventor: Chang-Hung Tsai, Miaoli County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/163,720

(22) Filed: Oct. 28, 2005

(51) Int. Cl. G01R 31/00

(52) U.S. Cl. 324/770

(57) ABSTRACT

A method of preventing display panel from burn-in defect is provided, suitable for regulating an image on the display area, and the display panel includes a plurality of pixels. The method includes the following steps. First, a first shifting signal is outputted to make the image on the display area shift a first distance along a first direction. Moreover, a second shifting signal is outputted to make the image on the display area shift a second distance along a second direction. The method can prevent the display panel from the burn-in defect when the display panel displays a static image or an image with a fixed position on the display area for a long period.

### BACKGROUND OF THE INVENTION

1. Field of Invention

The present invention relates to a method of protecting display panel. More particularly, the present invention relates to a method of preventing display panel from producing burn-in defect.

2. Description of Related Art

In general, there are mainly two types of display devices, one is the monitor using cathode ray tube, and the other is flat panel display. Since the flat panel display saves more power than the monitor using cathode ray tube, and also has smaller volume, the flat panel display has gradually become the most favored display product in the market. The common flat panel display in the current market includes liquid crystal display (LCD) and plasma display panel (PDP), etc. Wherein, the PDP can be made into large-sized display panel, therefore often serving as the screen for television.

However, when the display panel displays a static image or an image with fixed position on the screen for a long period, a burn-in defect could be produced on the display panel of PDP, and the display performance of the PDP would be reduced and also the life of the PDP would be shortened. Generally speaking, in order to improve the burn-in defect produced on the display area, when the display panel displays a static image for a long period, a full white is displayed on the screen to change the status of the image with a fixed position on the display area, thus improving the burn-in defect produced on the screen.

Or, the burn-in defect produced on the display panel can be improved by image reversing. For example, when the image on the display area is a red area, the red on the display area is reversed to the complementary color; that is, the red area is reversed into cyan (the complementary color of red) area to prevent the image from staying at the fixed position on the display area.

For the aforementioned two methods of preventing display panel from burn-in defect, the first method may result in a full white image on the display area and a great deal of fluorescein in the display device is ablated, then the life of the display device may be shortened. However, in the second method, users can not see the original color of the image.

### SUMMARY OF THE INVENTION

Accordingly, the present invention is directed to a method of preventing display panel from burn-in defect, which can elongate the life of the display panel.

The present invention provides a method of preventing display panel from burn-in defect, wherein the method is suitable for regulating an image displayed in the display area of a display panel, and the display panel includes a plurality of pixels. The method includes the following steps. First, a first shifting signal is outputted to make the image on the display area shift a first distance along a first direction. Then, a second shifting signal is outputted to make the image in the display area shift a second distance along a second direction.

In the method of preventing display panel from burn-in defect in one embodiment of the present invention, the first direction is, for example, the horizontal direction of the display area.

In the method of preventing display panel from burn-in defect in one embodiment of the present invention, the second direction is, for example, the vertical direction of the display area.

The method of preventing display panel from burn-in defect in one embodiment of the present invention further includes: outputting a third shifting signal to make the image in the display area shift a third distance along a third direction, then outputting a fourth shifting signal to make the image on the image area shift a fourth distance along a fourth direction.

In the method of preventing display panel from burn-in defect in one embodiment of the present invention, the first direction is, for example, toward the left of the display area, and the second direction is, for example, toward the top right of the display area. In addition, the third direction is, for example, toward the left of the display area, and the fourth direction is, for example, toward the bottom right of the display area.

In the method of preventing display panel from burn-in defect in one embodiment of the present invention, the first distance is, for example, the distance of at least three pixels.

In the method of preventing display panel from burn-in defect in one embodiment of the present invention, the first distance is, for example, the distance between three pixels and six pixels.

In the method of preventing display panel from burn-in defect in one embodiment of the present invention, the second distance is, for example, the distance of at least three pixels.

In the method of preventing display panel from burn-in defect in one embodiment of the present invention, the second distance is, for example, the distance of between three pixels and six pixels.

In the method of preventing display panel from burn-in defect in one embodiment of the present invention, the period for the image on the display area to shift a first distance along a first direction and the period for the image on the display area to shift a second distance along a second direction are between 1 second and 255 seconds, respectively.

In summary, the method of preventing display panel from burn-in defect in one embodiment of the present invention can regulate the image on the display area properly to prevent the display panel from producing burn-in defect, and further elongate the life of the display panel.

In order to the make the aforementioned and other objects, features and advantages of the present invention comprehensible, a preferred embodiment accompanied with figures is described in detail below.

### BRIEF DESCRIPTION OF THE DRAWINGS

FIG. 1 is a schematic diagram of a PDP according to one embodiment of the present invention.

FIG. 2 is a partially enlarged schematic diagram of a PDP according to one embodiment of the present invention.

FIGS. 3A and 3B are schematic flow charts of regulating the image by the display area according to one embodiment of the present invention.

FIGS. 4A to 4D are schematic flow charts of regulating the image by the display area according to one embodiment of in the present invention.

### DESCRIPTION OF EMBODIMENTS

In order to illustrate the method of preventing display panel from producing burn-in defect in the present invention, the PDP is taken as an example to describe the following embodiments. Of course, the application scope of the method of preventing display panel from producing burn-in defect is not limited thereto. After referring to the following embodiments, those skilled in the art should be able to apply the method of the present invention as needed to protect other display devices using fluorescein materials to produce color images.

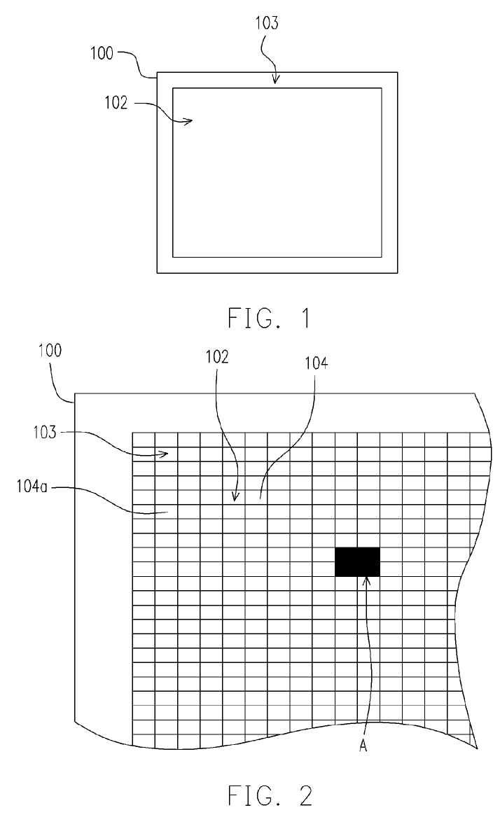

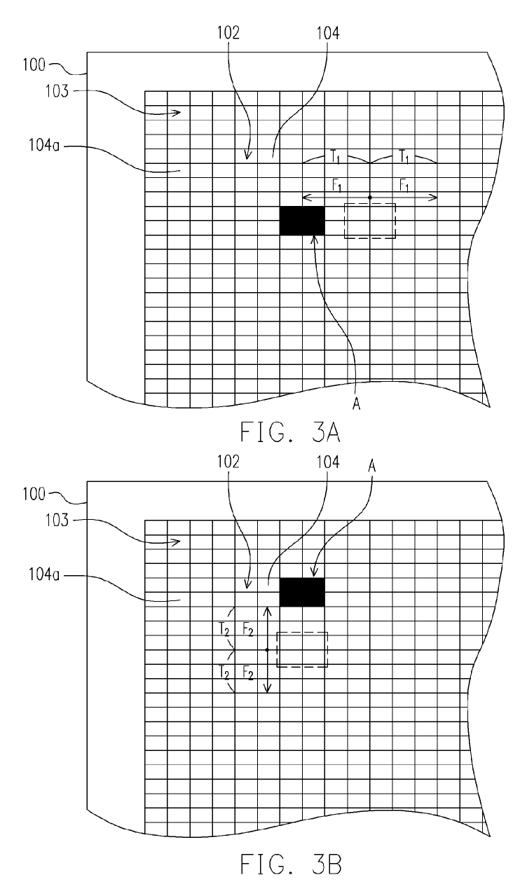

FIG. 1 is a schematic diagram of a PDP according to an embodiment of the present invention, and FIG. 2 is a partially enlarged schematic diagram of a PDP according to an embodiment of the present invention. Please refer to FIG. 1 and FIG. 2. The PDP 100 in the embodiment mainly includes a display area 102 and a plurality of pixels 104 configured in the display area 102. And generally, pixels 104a can also be formed in the non-display area region 103 of the PDP 100. Wherein, the number of the pixels 104 depends on the resolution requirement of the display area 102. With the same size of the display area 102, the higher requirement of the resolution in the display area, the high number of the pixels 104. That is, more pixels 104 are required to represent the details of the image in the display area.

The display theory of the display panel 100 is as follows. Since the inert gases (Ne, He, Xe, etc.) within the PDP 100 will produce ultraviolet radiation when discharging, the different color fluorescence materials will emit visible lights with different wavelengths after excited by the ultraviolet light, so that the image is displayed. When the pixels 104 of the PDP 100 are lightened for a long period to display the image A, the fluorescence materials (not shown) at the image A would be excited for a long period, and the fluorescence materials would be over ablated, thus producing burn-in defect in the PDP 100.

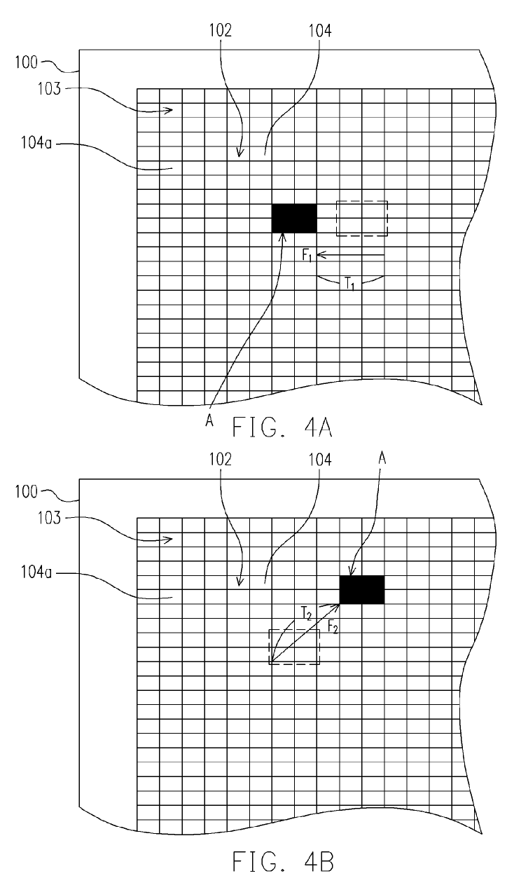

FIGS. 3A and 3B are schematic flow charts of regulating the image on the display panel. Please refer to FIG. 3A. In order to prevent the burn-in defect on the display panel 100 in FIG. 2, the present method includes the following steps: first, outputting a first shifting signal S1 to make the image A in the display area 102 at the original position in FIG. 2 shift a first distance T1 along a first direction F1, so that the image A in the display area 102 will shift a first distance T1 along a first direction F1. The dotted line in FIG. 3A marks the original position where the image A is located. Wherein, the first direction F1 is, for example, the horizontal direction (to the left or the right horizontally) relative to the display area 102, and the first distance T1 is, for example, the distance of at least three pixels. In addition, the period for the image A on the display area 102 to shift a first distance T1 along the first direction F1 can be selected according to a user's requirement, and the period is, for example, between 1 second and 255 seconds.

Next, please refer to FIG. 3B. A second shifting signal S2 is outputted to make the image A on the display area 102 shift a second distance T2 along a second direction F2. The aforementioned second direction F2 is, for example, the vertical direction (upward or downward vertically) relative to the display area 102, and the second distance T2 is, for example, the distance of at least three pixels. In addition, the period for the image A on the display area 102 to shift a second distance T2 along the second direction F2 is, for example, between 1 second and 255 seconds. Therefore, the image shifting in the display area 102 can improve the condition of the image A staying at the fixed position for a long period, further achieve the purpose of preventing the PDP 100 from burn-in defect.

Of course, the embodiment does not intend to limit the sequence of the horizontal or vertical directions of regulating the image on the display area; that is, the first direction can be set to vertical direction and the second direction can be set to horizontal direction. In other words, the parameters of the distance and period of the image movement can be selected as needed, as long as the image on the display area shifts in more than two directions.

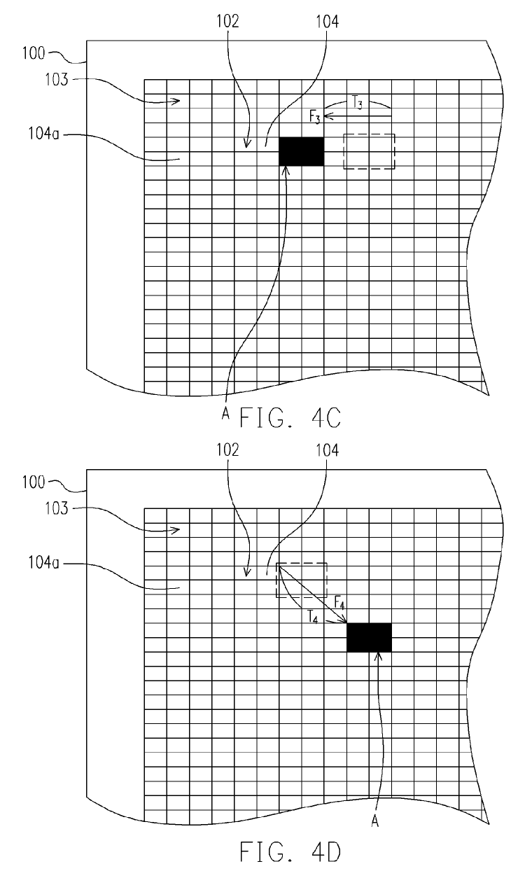

As mentioned above, the preferred shifting distance of the image on the display area is taken as an example to describe the following embodiments. FIGS. 4A to 4D are schematic flowcharts of regulating the image on the display area in the present invention. Please refer to FIG. 4A. First, a first shifting signal S1 is outputted to make the image A (as shown in FIG. 2) in the display area 102 shift a first distance T1 along a first direction F1 (for example, left), and the first distance T1 is, for example, the distance of three pixels. And, the dotted line position in FIG. 4A marks the original position where the image A is located in FIG. 2. Wherein, the first distance T1 can be selected as needed, and the scope is, for example, the distance of at least three pixels, and the preferred distance is between three pixels and six pixels. Of course, with different size of the display panel 100, the first distance T1 can be selected properly according to the actual resolution of the PDP 100 in order to ensure the protection of the display area 102. In addition, the period for the image A to shift to the next position from the position marked by the dotted line can be set to, for example, between 1 second and 255 seconds.

Please refer to FIG. 4B. Next, for example, a second shifting signal S2 is outputted to make the image on the display area 102 shift rightward horizontally and upward vertically. Accordingly, the image A in the display area 102 shifts a second distance T2 along a second direction F2 (for example, top right). And, the dotted line position in FIG. 4B marks the original position where the image A is located in FIG. 4A. Wherein the scope of the second distance T2 is, for example, the distance of three pixels, and the preferred distance is between three pixels and six pixels. The second distance T2 can be selected properly as needed. In addition, the period for the image A to shift to the next position from the position marked by the dotted line can be set to, for example, between 1 second and 255 seconds.

Next, please refer to FIG. 4C. For example, a third shifting signal S3 is outputted to make the image A on the display area 102 shift a third distance T3 along the third direction F3 (for example, left), and the dotted line position in FIG. 4C marks the original position where the image A is located in FIG. 4B. Wherein the scope of the third distance T3 is, for example, the distance of three pixels, and the preferred distance is between three pixels and six pixels. The third distance T3 can be selected properly as needed. In addition, the period for the image A to shift to the next position from the position marked by the dotted line can be set to, for example, between 1 second and 255 seconds.

Finally, please refer to FIG. 4D. For example, a fourth shifting signal S4 is outputted to make the image on the display area 102 shift rightward horizontally and downward vertically. Accordingly, the image A in the display area 102 shifts a fourth distance T4 along a fourth direction F4 (for example, bottom right). And, the dotted line position in FIG. 4D marks the original position where the image A is located in FIG. 4. Finally the image A returns to the original position in the display area in FIG. 2. Wherein the scope of the fourth distance T4 is, for example, the distance of three pixels, and the preferred distance is between three pixels and six pixels. The fourth distance T4 can be selected properly as needed. In addition, the period for the image A to shift to the next position from the position marked by the dotted line can be set to, for example, between 1 second and 255 seconds.

As mentioned above, the image A is made to repeatedly shift slightly along the aforementioned distances in sequence. Accordingly, the image can be prevented from staying at a fixed position on the display area 102 for a long period, and further the display panel is prevented from producing burn-in defect and also the life of the display panel 100 can be elongated. In addition, the method of preventing display panel from burn-in defect of the present invention only makes the display image (image A) on the display panel 102 shift slightly, so that users can still identify the profile and the real color of the display image (image A).

In summary, the method of preventing display panel from burn-in defect of the present invention has at least the following advantages:

First, when the display panel displays a static image or an image with a fixed position on the display area for a long period, the original image is made to shift slightly to prevent the display panel from producing burn-in defect and also enlogate the life of the display panel.

Second, the method of preventing display panel from burn-in defect of the present invention can achieve the purpose of protecting the display panel by regulating the movement of the image on the display area. Therefore, the real color of the image is not affected, and users can still identify the profile and the real color of the display image.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of preventing display panel from burn-in defect, suitable for regulating an image displayed in a display area of a display panel, and the display panel comprising a plurality of pixels; the method comprising:
outputting a first shifting signal to make the image on the display area shift a first distance along a first direction; and
outputting a second shifting signal to make the image on the display area shift a second distance along a second direction.

2. The method of preventing display panel from burn-in defect as claimed in claim 1, wherein the first direction is the horizontal direction of the display area.

3. The method of preventing display panel from burn-in defect as claimed in claim 1, wherein the second direction is the vertical direction of the display area.

4. The method of preventing display panel from burn-in defect, further comprising:
outputting a third shifting signal to make the image on the display area shift a third distance along a third direction; and
outputting a fourth shifting signal to make the image on the display area shift a fourth distance along a fourth direction.

5. The method of preventing display panel from burn-in defect as claimed in claim 4, wherein
the first direction is toward the left of the display area;
the second direction is toward the top right of the display area;
the third direction is toward the left of the display area; and
the fourth direction is toward the bottom right of the display area.

6. The method of preventing display panel from burn-in defect as claimed in claim 1, wherein the first distance is the distance of at least three pixels.

7. The method of preventing display panel from burn-in defect as claimed in claim 6, wherein the first distance is the distance between three pixels and six pixels.

8. The method of preventing display panel from burn-in defect as claimed in claim 1, wherein the second distance is the distance of at least three pixels.

9. The method of preventing display panel from burn-in defect as claimed in claim 8, wherein the second distance is the distance between three pixels and six pixels.

10. The method of preventing display panel from burn-in defect as claimed in claim 1, wherein the period for the image on the display area to shift a first distance along a first direction and the period for the image on the display area to shift a second distance along a second direction are between 1 second and 255 seconds, respectively.
